(19) United States
(12) Patent Application Publication
(10) Pub. No.: US 2025/0202518 A1
(43) Pub. Date: Jun. 19, 2025

(54) ELECTRONIC CIRCUIT, AD CONVERSION DEVICE, COMMUNICATION DEVICE, AND CONTROL METHOD

(71) Applicant: SONY SEMICONDUCTOR SOLUTIONS CORPORATION, KANAGAWA (JP)

(72) Inventor: TOMOAKI SATO, KANAGAWA (JP)

(21) Appl. No.: 18/846,508

(22) PCT Filed: Feb. 7, 2023
(86) PCT No.: PCT/JP2023/003904

§ 371 Date: Sep. 12, 2024

(30) Foreign Application Priority Data
Mar. 23, 2022 (JP) 2022-047371

(51) Int. Cl. H04B 1/16; H03M 1/12; H04B 1/12

(52) U.S. Cl. CPC H04B 1/1607; H03M 1/129; H04B 1/12

(57) ABSTRACT

Provided is an electronic circuit, an AD conversion device, and a communication device capable of suppressing power consumption of a circuit configured in a preceding stage of an analog-to-digital converter. An electronic circuit includes a pre-stage circuit configured to supply an analog signal to an analog-to-digital converter that performs different driving in a first period and a second period, and a control circuit configured to reduce a supply current to the pre-stage circuit according to the first period.

### TECHNICAL FIELD

The present disclosure relates to an electronic circuit, an AD conversion device, a communication device, and a control method.

### BACKGROUND ART

An electronic circuit configured at a preceding stage of the analog-to-digital converter supplies an analog signal to the analog-to-digital converter. The analog-to-digital converter has a hold period for converting an analog signal into a digital signal.

### CITATION LIST

### Patent Document

Patent Document 1: Japanese Patent Application Laid-Open No. 2005-86550

### SUMMARY OF THE INVENTION

### Problems to be Solved by the Invention

However, an electronic circuit configured at the preceding stage of an analog-to-digital converter continues normal driving even during a hold period of the analog-to-digital converter, and there is a risk that power consumption increases.

Therefore, the present disclosure provides an electronic circuit, an AD conversion device, a communication device, and a control method capable of suppressing power consumption of a circuit configured at a preceding stage of an analog-to-digital converter.

### Solutions to Problems

In order to solve the above problem, according to the present disclosure, there is provided an electronic circuit including: a pre-stage circuit configured to supply an analog signal to an analog-to-digital converter that performs different driving in a first period and a second period; and a control circuit configured to reduce a supply current to the pre-stage circuit according to the first period.

The first period and the second period may be periodically and alternately repeated, and the control circuit may reduce a supply current to the pre-stage circuit in synchronization with the alternately repeated cycle.

The first period may depend on a period during which the analog-to-digital converter converts an analog signal to a digital signal.

The control circuit may cause the pre-stage circuit to supply a first current in the first period, and cause the pre-stage circuit to supply a second current smaller than the first current in the second period.

The control circuit may be synchronized with the cycle on a basis of a clock signal.

The second period may be set according to an activation characteristic of the pre-stage circuit.

The second period may be set according to time to reach an operating point in a case where the first current is always supplied to the pre-stage circuit.

The pre-stage circuit may include at least an amplifier that supplies an analog signal to the analog-to-digital converter.

The amplifier may be configured by a plurality of amplifiers connected in parallel, and the control circuit may block a supply current to at least one amplifier among the plurality of amplifiers in the second period.

The electronic circuit further includes a current source configured to supply the supply current to the pre-stage circuit, and the control circuit may control a current output from the current source.

The pre-stage circuit may include: a low noise amplifier that amplifies a signal in a high frequency region received by a reception antenna; and a frequency mixer that converts a carrier frequency of an output signal of the low noise amplifier into a lower intermediate frequency by mixing an oscillation frequency of a voltage controlled oscillator, and the amplifier may amplify a signal converted into an intermediate frequency by the frequency mixer.

The pre-stage circuit may include: a low noise transconductance amplifier that operates on a capacitive load and amplifies a signal in a high frequency region received by a reception antenna; a frequency mixer that converts a carrier frequency of an output signal of the low noise transconductance amplifier into a lower intermediate frequency by mixing an oscillation frequency of a voltage controlled oscillator; and a transimpedance amplifier that amplifies a signal output from the frequency mixer as a voltage signal, and the amplifier may limit a band of a signal output from the transimpedance amplifier and amplify a signal with reduced noise.

In order to solve the above problems, according to the present disclosure, there is provided an AD conversion device including: the above-described electronic circuit; and the analog-to-digital converter.

In order to solve the above problem, according to the present disclosure, there is provided a communication device including: a reception device including the above-described electronic circuit; and a transmission device.

In order to solve the above problem, according to the present disclosure, there is provided a control method of a pre-stage circuit that supplies an analog signal to an analog-to-digital converter in which a first period and a second period are periodically and alternately repeated, the analog-to-digital converter performing different driving in the first period and the second period, the control method including: inputting a clock signal; and reducing a supply current to the pre-stage circuit according to the first period on a basis of a clock signal.

### BRIEF DESCRIPTION OF DRAWINGS

FIG. 1 is a block diagram illustrating a configuration example of a communication device including an electronic circuit according to a first embodiment.

FIG. 2 is a diagram for explaining an operation example of an analog-to-digital converter.

FIG. 3 is a diagram illustrating a configuration example of a control circuit according to the present embodiment.

FIG. 4 is a timing chart illustrating control timing.

FIG. 5 is a diagram schematically illustrating an example in which a supply current to the analog-to-digital converter is set to 0 in a hold period.

FIG. 6 is a diagram illustrating an example of a settling period in a case where a supply current to the analog-to-digital converter is set to 0 in a hold period.

FIG. 7 is a diagram schematically illustrating an example in which a supply current to the analog-to-digital converter in a hold period is Ib.

FIG. 8 is a diagram illustrating an example of a settling period in a case where a supply current to the analog-to-digital converter is set to 0 in a hold period.

FIG. 9 is a diagram illustrating a configuration example of an electronic circuit according to a first modification of the first embodiment.

FIG. 10 is a diagram illustrating a configuration example of an electronic circuit at a preceding stage in a reception device according to a second modification of the first embodiment.

FIG. 11 is a diagram illustrating a configuration example of an amplifier in a reception device according to a second embodiment.

FIG. 12 is a diagram illustrating a control example of a control circuit according to the second embodiment.

FIG. 13 is a diagram illustrating an example of an effect of control according to the second embodiment.

### MODE FOR CARRYING OUT THE INVENTION

Hereinafter, embodiments of an electronic circuit, an AD conversion device, a communication device, and a control method will be described with reference to the drawings. Hereinafter, the main components of the electronic circuit, the AD conversion device, the communication device, and the control method will be mainly described, but the electronic circuit, the AD conversion device, the communication device, and the control method may include components and functions that are not illustrated or described. The following description does not exclude components and functions that are not depicted or described.

### First Embodiment

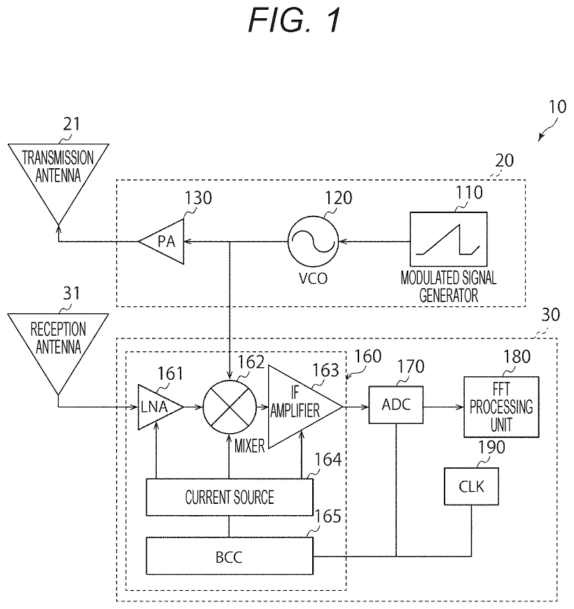

Hereinafter, a communication device according to a first embodiment will be described. FIG. 1 is a block diagram illustrating a configuration example of a communication device 10 including an electronic circuit 160 according to the first embodiment.

The communication device 10 can use, for example, a radar device that transmits a radio wave such as a millimeter wave toward an object, receives a reflected wave thereof, and measures a distance to the object by a time difference. The communication device 10 includes a transmission device 20, a transmission antenna 21, a reception device 30, and a reception antenna 31. In the case of the radar device, it is common to provide the transmission antenna 21 and the reception antenna 31 separately. The transmission device 20 includes a modulated signal generator 110, a voltage controlled oscillator 120, and a power amplifier 130.

In addition, the reception device 30 includes the electronic circuit 160, an analog-to-digital converter (ADC) 170, an FFT processing unit 180, and a clock generator 190. The electronic circuit 160 is an electronic circuit configured at a preceding stage of the analog-to-digital converter (ADC) 170, and is a circuit capable of changing control driving according to a sampling period and a hold period of the analog-to-digital converter 170. The electronic circuit 160 includes a low noise amplifier 161, a frequency mixer 162, an intermediate frequency amplifier 163, a current source 164, and a control circuit 165. Further, the pre-stage circuit according to the present embodiment includes the low noise amplifier 161, the frequency mixer 162, and the intermediate frequency amplifier 163. In addition, the electronic circuit 160, the analog-to-digital converter (ADC) 170, and the clock generator 190 according to the present embodiment correspond to an AD conversion device. That is, the AD conversion device according to the present embodiment includes the electronic circuit 160, the analog-to-digital converter (ADC) 170, and the clock generator 190.

The modulated signal generator 110 of the transmission device 20 generates a modulated signal obtained by modulating a carrier wave to be transmitted. The voltage controlled oscillator (VCO) 120 is an oscillator that controls an oscillation frequency used for transmission and reception by a control voltage. The power amplifier (PA) 130 amplifies the power of a transmission signal by the oscillation frequency of the voltage controlled oscillator 120 and transmits the signal through the transmission antenna 21.

The low noise amplifier (LNA) 161 of the electronic circuit 160 amplifies a signal in a high frequency region received by the reception antenna 31. The frequency mixer 162 converts the carrier frequency of an output signal of the low noise amplifier 161 into a lower intermediate frequency by mixing the oscillation frequency of the voltage controlled oscillator 120. The intermediate frequency (IF) amplifier 163 is an amplifier that amplifies a signal converted to an intermediate frequency by the frequency mixer 162.

The control circuit 165 includes, for example, a CPU, and changes control driving of the electronic circuit 160 according to a sampling period and a hold period of the analog-to-digital converter 170 on the basis of a clock signal of the clock generator 190. A control example of the control circuit 165 will be described later.

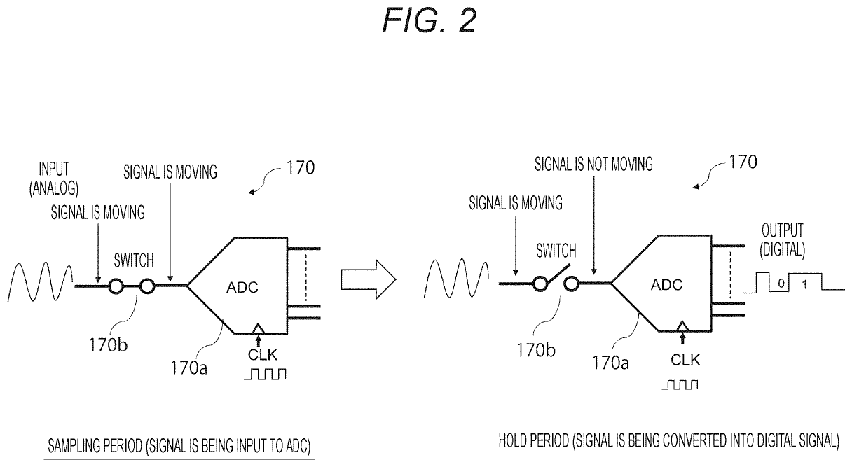

The analog-to-digital converter (ADC) 170 converts an output of the intermediate frequency amplifier 163 from an analog signal to a digital signal. FIG. 2 is a diagram for explaining an operation example of the analog-to-digital converter 170. As illustrated in FIG. 2, the analog-to-digital converter 170 includes an analog-to-digital conversion unit 170a and a switching element 170b. The analog-to-digital conversion unit 170a holds the sampled analog signal and converts the analog signal into digital data. The switching element 170b has one end connected to the intermediate frequency amplifier 163 and the other end connected to the analog-to-digital conversion unit 170a.

The sampling period according to the present embodiment corresponds to a period during which an analog signal is input to the analog-to-digital converter 170. In this period, the switching element 170b is in a connected state.

On the other hand, the hold period according to the present embodiment corresponds to a period in which the analog-to-digital converter 170 converts an analog signal into a digital signal. In this period, the switching element 170b is in a disconnected state. Thus, the switching element 170b blocks an input signal to the analog-to-digital conversion unit 170a according to the hold period. In other words, in the hold period, the signal from the electronic circuit 160 becomes unnecessary. Therefore, even if the driving of the electronic circuit 160 is suppressed in the hold period, the conversion of the data held in the sampling period of the analog-to-digital converter 170 into the digital data is not affected.

The fast Fourier transform (FFT) processing unit 180 performs fast Fourier transform (FFT) processing on the output of the analog-to-digital converter 170 to extract a necessary signal. The clock generator 190 generates and supplies a clock signal to the control circuit 165 and the analog-to-digital converter 170.

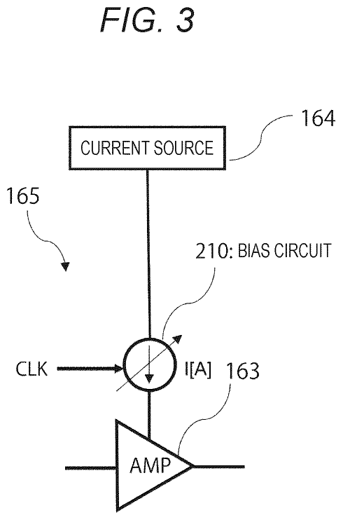

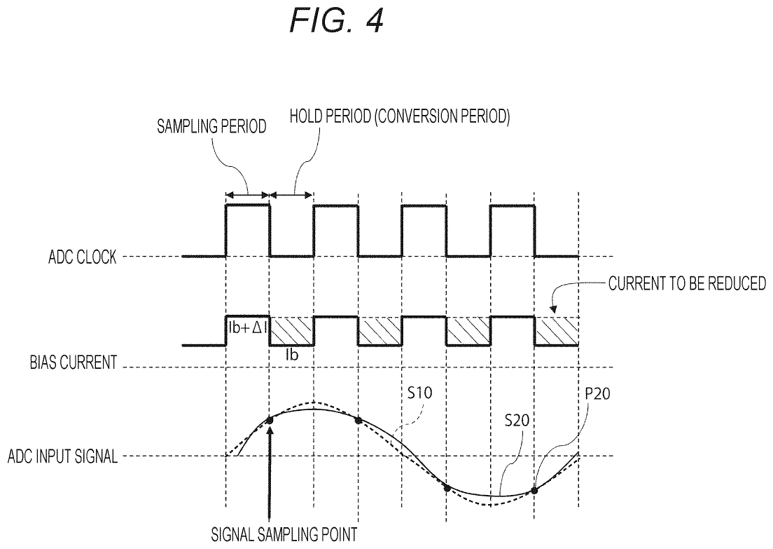

Here, details of the control circuit 165 will be described with reference to FIGS. 3 and 4. FIG. 3 is a diagram illustrating a configuration example of the control circuit 165 according to the present embodiment. The control circuit 165 includes a bias circuit 210 that controls the amount of current supplied from the current source 300. That is, the control circuit 165 controls the amount of current supplied from the current source 300 on the basis of the signal of the clock generator 190. In FIG. 3, only an example of current supply to the intermediate frequency amplifier 163 is illustrated, but the present invention is not limited thereto, and the amount of current supply to the low noise amplifier 161, the frequency mixer 162, and the like may also be controlled.

FIG. 4 is a timing chart illustrating control timing of the control circuit 165. The horizontal axis of FIG. 4 represents time. An ADC clock, a bias current, and an ADC input signal are illustrated from the top. The ADC clock is a clock indicating a cycle of the sampling period and the hold period in the analog-to-digital converter 170 based on a signal of the clock generator 190. The high-level signal corresponds to the sampling period, and the low-level signal corresponds to the hold period. Further, the hold period according to the present embodiment corresponds to a first period, and the sampling period corresponds to a second period.

The bias current indicates a supply current from the current source 300 under the control of the bias circuit 210. A normal current Ib+ΔI is an example of a current supplied to the electronic circuit 160 in the sampling period, and a suppressed current Ib is an example of a current supplied to the electronic circuit 160 in the hold period.

This sampling period corresponds to a period during which the electronic circuit 160 returns to the normal driving state when the suppressed current Ib is returned to the normal current Ib+ΔI. In other words, the sampling period is set in consideration of an activation characteristic such as a transient response of the electronic circuit 160. Therefore, even if the suppressed current Ib flows through the electronic circuit 160, the influence on the analog-to-digital converter 170 is suppressed.

An ADC input signal S10 is an example of an analog signal of the electronic circuit 160 in a case where the current Ib+ΔI flows also during the hold period. On the other hand, a sampling point P20 indicates a sampling value in a case where the current in the hold period is the suppressed current Ib and the normal current in the sampling period is Ib+ΔI. The signal S20 is a curve example in which the sampling points P20 are connected by splines. A curve S20 in which the sampling points P20 are connected by splines and the ADC input signal S10 in a case where the normal current Ib+ΔI flows also in the hold period show substantially similar curves.

The analog-to-digital converter 170 according to the present embodiment samples the analog value immediately before the end of the sampling period. That is, the value of the sampling point P20 corresponds to the digital value converted by the analog-to-digital converter 170. The signal S20 is a curve example in which the sampling points P20 are connected by splines.

As illustrated in FIG. 4, the control circuit 165 periodically varies the supply current Ib+ΔI from the current source 300 and Ib in synchronization with the ADC clock in the analog-to-digital converter 170 using the clock signal of the clock generator 190. On the other hand, the analog-to-digital converter 170 samples the analog value immediately before the end of the sampling period. That is, the value of the sampling point P20 corresponds to the digital value converted by the analog-to-digital converter 170. As described above, the sampling point P20 in a case where the current Ib is set during the hold period has a value substantially equal to the output value of the analog-to-digital converter 170 in a case where the current Ib+ΔI is also applied during the hold period.

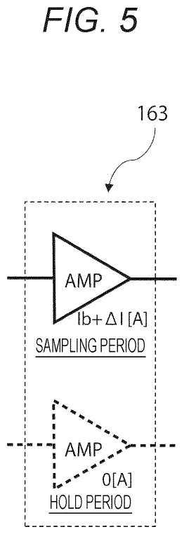

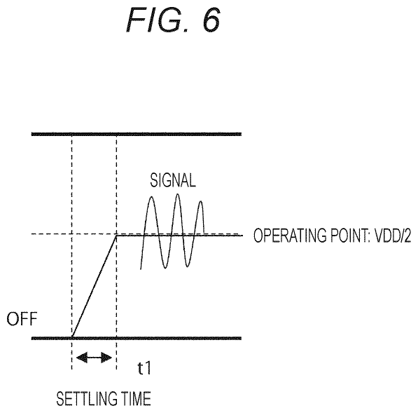

An example of a setting effect of the sampling period and the suppressed current Ib will be described with reference to FIGS. 5 to 8. FIG. 5 is a diagram schematically illustrating an example in which the supply current to the analog-to-digital converter 170 is set to 0 in the hold period. The hold period is the same as that in FIG. 4. FIG. 6 is a diagram illustrating an example of a settling period t1 in a case where the supply current to the analog-to-digital converter 170 is set to 0 in the hold period. The settling period is a time until the operating point of the electronic circuit 160 returns to normal driving.

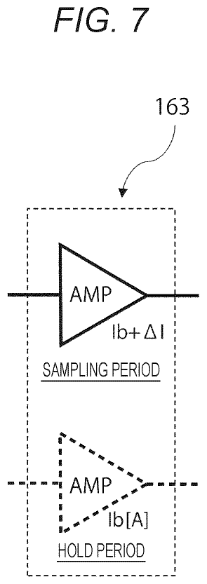

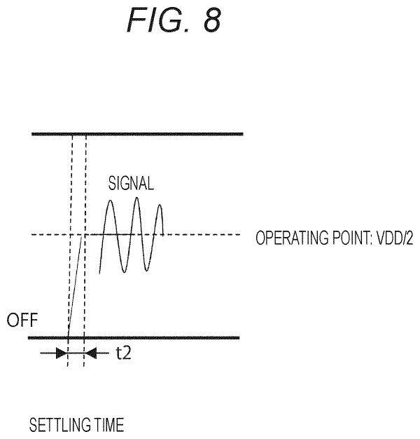

FIG. 7 is a diagram schematically illustrating an example in which the supply current to the analog-to-digital converter 170 in the hold period is set to Ib. The hold period is the same as that in FIG. 4. FIG. 8 is a diagram illustrating an example of a settling period t2 in a case where the supply current to the analog-to-digital converter 170 is suppressed to Ib in the hold period. The settling period is a time until the operating point returns to normal driving. When t2<t1 is satisfied and the suppressed current Ib continues to flow even during the hold period, the time until the operating point of the analog-to-digital converter 170 returns to the normal driving can be shortened. In other words, the sampling period is always set according to the time to reach the operating point in a case where the normal current Ib+ΔI is supplied to the electronic circuit 160. That is, the suppressed current Ib is set within a range in which a delay from the operating point in the case of supplying the suppressed current Ib to the electronic circuit 160 is allowed.

In this manner, the values of the sampling period and the suppressed current Ib are set in consideration of activation characteristics such as a transient response of the electronic circuit 160. As the suppressed current Ib is decreased, the sampling period needs to be made longer. In other words, the sampling period is set to correspond to a period during which the electronic circuit 160 returns to the normal driving state when the suppressed current Ib is returned to the normal current Ib+ΔI. As described above, the sampling period is always set according to the time to reach the operating point in a case where the normal current Ib+ΔI is supplied to the electronic circuit 160. Therefore, even if the suppressed current Ib flows through the electronic circuit 160, the influence on the analog-to-digital converter 170 is suppressed. As can be seen from these, it is possible to suppress the power consumption in the hold period according to the decrease in the current ΔI while maintaining the conversion accuracy by setting the values of the sampling period and the suppressed current Ib in consideration of characteristics such as a transient response of the electronic circuit 160.

As described above, in the electronic circuit 160 according to the present embodiment, the control circuit 165 reduces the current supplied to the electronic circuit 160 to the suppressed current Ib according to the hold period that is an analog-digital conversion period of the analog-to-digital converter 170. Therefore, the power consumption of the electronic circuit 160 can be suppressed while maintaining the conversion accuracy of the analog-to-digital converter 170. In addition, it is possible to suppress a decrease in conversion accuracy of the analog-to-digital converter 170 by setting the values of the sampling period and the suppressed current Ib in consideration of activation characteristics such as a transient response of the electronic circuit 160.

### First Modification of First Embodiment

The electronic circuit 160 according to the first embodiment also includes the low noise amplifier 161, the frequency mixer 162, and the like, but an electronic circuit 160a according to a first modification of the first embodiment is different from the electronic circuit 160 according to the first embodiment in that the electronic circuit 160a includes a buffer amplifier 165 and a control circuit 200.

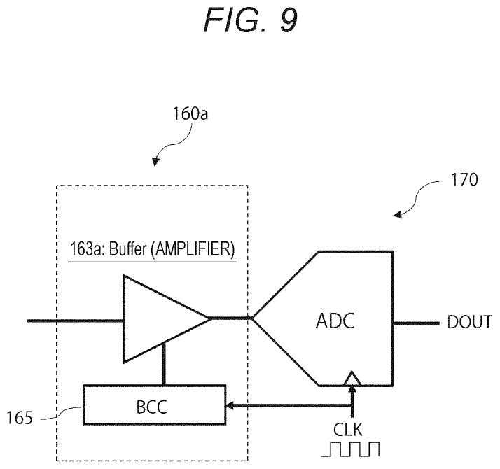

FIG. 9 is a diagram illustrating a configuration example of the electronic circuit 160a according to the first modification of the first embodiment. As illustrated in FIG. 9, the electronic circuit 160a according to the first modification of the first embodiment includes the buffer amplifier 165 and the control circuit 200. The buffer amplifier 165 is an amplifier capable of amplifying and outputting an input signal without changing the signal. The electronic circuit 160a is applicable to an electronic device using the buffer amplifier 165 and the analog-to-digital converter 170. Therefore, it is possible to suppress the power consumption of the electronic device using the buffer amplifier (Buffer) 165 and the analog-to-digital converter 170.

### Second Modification of First Embodiment

The electronic circuit 160 according to the first embodiment is of a voltage conversion system, but an electronic circuit 160b according to a second modification of the first embodiment is different from the electronic circuit 160 according to the first embodiment in that the electronic circuit 160b is of a current conversion system. Hereinafter, a difference from the electronic circuit 160 according to the first embodiment is described.

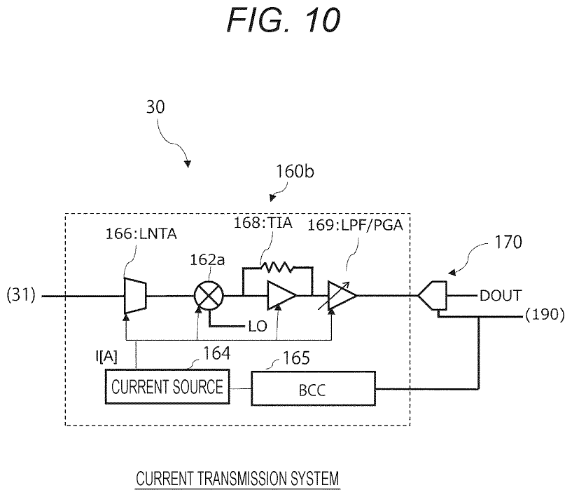

FIG. 10 is a diagram illustrating a configuration example of the electronic circuit 160b at a preceding stage in the reception device 30 according to the second modification of the first embodiment. As illustrated in FIG. 10, the electronic circuit 160b is of a current transmission system, and includes a low noise transconductance amplifier 166, a frequency mixer 162a, a transimpedance amplifier 168, a low noise programmable gain amplifier 169, a current source 164, and a control circuit 165.

A low noise transconductance amplifier (LNTA) 166 of the electronic circuit 160b amplifies a current signal in the high frequency region received by the reception antenna 31 (see FIG. 1). For example, the low noise transconductance amplifier 166 operates on capacitive loads and has higher linearity and gain over a wide frequency band.

The frequency mixer 162a converts the carrier frequency of an output signal of the low noise transconductance amplifier 166 into a lower intermediate frequency by mixing the oscillation frequency of the voltage controlled oscillator 120. The transimpedance amplifier (TIA) 168 converts a current signal into impedance and amplifies the impedance as a voltage signal.

The low noise programmable gain amplifier 169 includes a low pass filter (LPF) and a programmable gain amplifier (PGA). The low pass filter limits the band and suppresses, for example, a predetermined broadband signal. The programmable gain amplifier is an amplifier whose gain can be changed by an external input (for example, a digital value), amplifies a signal with reduced noise by a low pass filter, and outputs the signal to the analog-to-digital converter 170.

Similarly to the first embodiment, the control circuit 165 changes the control driving in the electronic circuit electronic circuit 160b of the current conversion system according to the sampling period and the hold period of the analog-to-digital converter 170 on the basis of the clock signal of the clock generator 190. That is, the control circuit 165 controls the current supplied from the current source 164 to the low noise transconductance amplifier 166, the frequency mixer 162a, the transimpedance amplifier 168, and the low noise programmable gain amplifier 169 according to the sampling period and the hold period of the analog-to-digital converter 170. That is, in the electronic circuit 160b according to the present embodiment, the control circuit 165 reduces the current supplied to the electronic circuit 160b of the current conversion system to the suppressed current Ic according to the hold period that is the analog-digital conversion period of the analog-to-digital converter 170.

Therefore, similarly to the first embodiment, it is possible to suppress the power consumption of the electronic circuit 160b while maintaining the conversion accuracy of the analog-to-digital converter 170. In addition, it is possible to suppress a decrease in conversion accuracy of the analog-to-digital converter 170 by setting the values of the sampling period and the suppressed current Ic in consideration of characteristics such as a transient response of the electronic circuit 160b.

### Second Embodiment

The electronic circuit 160 according to a second embodiment is different from the electronic circuit 160 according to the first embodiment in that an amplifiers 163 are connected in parallel, and the supply current to one amplifier is reduced according to the hold period of the analog-to-digital converter 170. Hereinafter, a difference from the electronic circuit 160 according to the first embodiment is described.

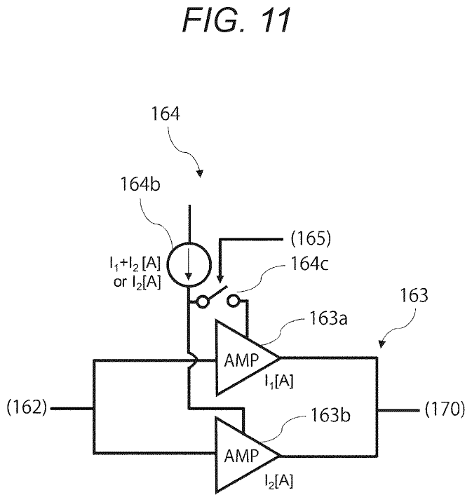

FIG. 11 is a diagram illustrating a configuration example of the amplifier 163 in the reception device 30 according to the second embodiment. Further, the amplifier 163 is an intermediate frequency amplifier, but is not limited thereto, and may be an amplifier having an amplification function. For example, an amplifier such as a buffer amplifier, a low noise transconductance amplifier, or a low noise programmable gain amplifier may be used.

As illustrated in FIG. 11, the amplifier 163 includes an amplifier 163a and an amplifier 163b connected in parallel. In addition, the current source 164 includes a current supply source 164b and a switching element 164c. One end of the switching element 164c is connected to the current supply source 164b, and the other end is connected to one amplifier 163a of the amplifier 163.

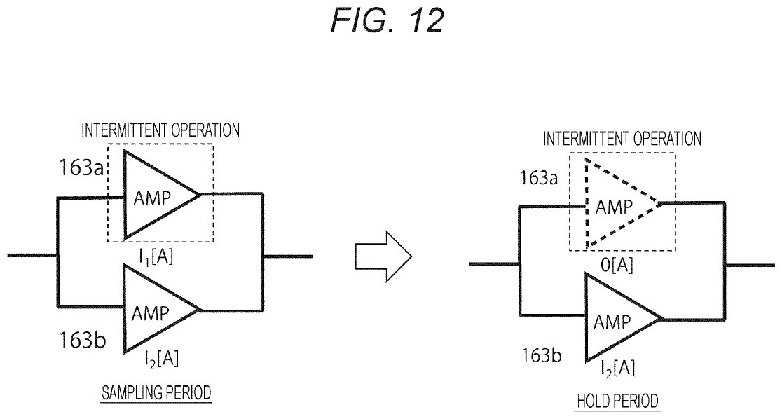

FIG. 12 is a diagram illustrating a control example of the control circuit 165 according to the second embodiment. The control circuit 165 according to the present embodiment intermittently operates only one amplifier amplifier 163a of the amplifier 163. That is, as illustrated in FIG. 11, the control circuit 165 according to the present embodiment brings the switching element 164c into the disconnected state according to the hold period that is the analog-digital conversion period of the analog-to-digital converter 170. Therefore, a normal current I1 is supplied to the one amplifier 163a during the sampling period of the analog-to-digital converter 170, and the suppressed current is reduced to 0 during the hold period. Further, in the present embodiment, the suppressed current is reduced to zero, but the present invention is not limited thereto. For example, the suppressed current may be a suppressed current Id or the like which is a current value lower than the normal current.

On the other hand, a normal current I2 is also supplied to the other amplifier 163b during the hold period. That is, the normal current 12 is always supplied to the amplifier 163b. Further, in the present embodiment, the normal current 12 is unchanged, but the present invention is not limited thereto. For example, the normal current 12 may also be suppressed according to the hold period.

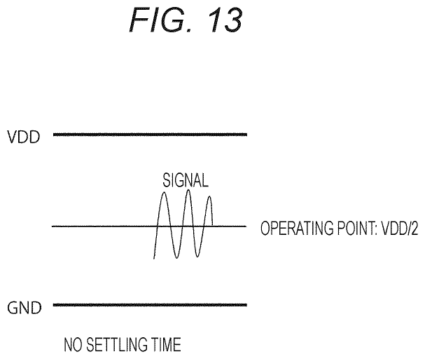

FIG. 13 is a diagram illustrating an example of an effect of control according to the second embodiment. As illustrated in FIG. 13, since the normal current I2 is always supplied to the one amplifier 163b even during the hold period, the settling period can be eliminated. On the other hand, since the switching element 164c is brought into the disconnected state according to the hold period which is the analog-digital conversion period of the analog-to-digital converter 170, it is possible to suppress the power consumption of one amplifier amplifier 163a of the amplifier 163.

Further, the present technology may have the following configurations.

(1)

An electronic circuit comprising:
a pre-stage circuit configured to supply an analog signal to an analog-to-digital converter that performs different driving in a first period and a second period; and
a control circuit configured to reduce a supply current to the pre-stage circuit according to the first period.

(2)

The electronic circuit according to (1), in which
the first period and the second period are periodically and alternately repeated, and
the control circuit reduces a supply current to the pre-stage circuit in synchronization with the alternately repeated cycle.

(3)

The electronic circuit according to (2), in which the first period depends on a period during which the analog-to-digital converter converts an analog signal to a digital signal.

(4)

The electronic circuit according to (3), in which the control circuit causes the pre-stage circuit to supply a first current in the first period, and causes the pre-stage circuit to supply a second current smaller than the first current in the second period.

(5)

The electronic circuit according to (4), in which the control circuit is synchronized with the cycle on a basis of a clock signal.

(6)

The electronic circuit according to (4), in which the second period is set according to an activation characteristic of the pre-stage circuit.

(7)

The electronic circuit according to (6), in which the second period is set according to time to reach an operating point in a case where the first current is always supplied to the pre-stage circuit.

(8)

The electronic circuit according to (4), in which the pre-stage circuit includes at least an amplifier that supplies an analog signal to the analog-to-digital converter.

(9)

The electronic circuit according to (8), in which
the amplifier is configured by a plurality of amplifiers connected in parallel, and
the control circuit blocks a supply current to at least one amplifier among the plurality of amplifiers in the second period.

(10)

The electronic circuit according to (9), further including
a current source configured to supply the supply current to the pre-stage circuit, in which
the control circuit controls a current output from the current source.

(11)

The electronic circuit according to (10), in which
the pre-stage circuit includes:
a low noise amplifier that amplifies a signal in a high frequency region received by a reception antenna; and
a frequency mixer that converts a carrier frequency of an output signal of the low noise amplifier into a lower intermediate frequency by mixing an oscillation frequency of a voltage controlled oscillator, and
the amplifier amplifies a signal converted into an intermediate frequency by the frequency mixer 162.

(12)

The electronic circuit according to (10), in which the pre-stage circuit includes:
a low noise transconductance amplifier that operates on a capacitive load and amplifies a signal in a high frequency region received by a reception antenna;
a frequency mixer that converts a carrier frequency of an output signal of the low noise transconductance amplifier into a lower intermediate frequency by mixing an oscillation frequency of a voltage controlled oscillator; and
a transimpedance amplifier that amplifies a signal output from the frequency mixer as a voltage signal, and the amplifier limits a band of a signal output from
the transimpedance amplifier and amplifies a signal with reduced noise.

(13)

An AD conversion device including:
the electronic circuit according to (1); and
the analog-to-digital converter.

(14)

A communication device including:
a reception device including the electronic circuit according to (1); and
a transmission device.

(15)

A control method of a pre-stage circuit that supplies an analog signal to an analog-to-digital converter in which a first period and a second period are periodically and alternately repeated, the analog-to-digital converter performing different driving in the first period and the second period, the control method comprising:
inputting a clock signal; and
reducing a supply current to the pre-stage circuit according to the first period on a basis of a clock signal.

Aspects of the present disclosure are not limited to the above-described individual embodiments, but include various modifications that can be conceived by those skilled in the art, and the effects of the present disclosure are not limited to the above-described contents. That is, various additions, modifications, and partial deletions are possible without departing from the conceptual idea and spirit of the present disclosure derived from the matters defined in the claims and equivalents thereof.

### REFERENCE SIGNS LIST

10 Communication device
20 Transmission device
30 Reception device
160, 160a, 160b Electronic circuit
161 Low noise amplifier
162, 162a Frequency mixer
163 Intermediate frequency amplifier
163a Buffer amplifier
164 Current source
165 Control circuit
166 Low noise transconductance amplifier
168 Transimpedance amplifier
169 Low noise programmable gain amplifier
170 Analog-to-digital converter
190 Clock generator

1. An electronic circuit comprising:
a pre-stage circuit configured to supply an analog signal to an analog-to-digital converter that performs different driving in a first period and a second period; and
a control circuit configured to reduce a supply current to the pre-stage circuit according to the first period.

2. The electronic circuit according to claim 1, wherein
the first period and the second period are periodically and alternately repeated, and
the control circuit reduces a supply current to the pre-stage circuit in synchronization with the alternately repeated cycle.

3. The electronic circuit according to claim 2, wherein the first period depends on a period during which the analog-to-digital converter converts an analog signal to a digital signal.

4. The electronic circuit according to claim 3, wherein the control circuit causes the pre-stage circuit to supply a first current in the first period, and causes the pre-stage circuit to supply a second current smaller than the first current in the second period.

5. The electronic circuit according to claim 4, wherein the control circuit is synchronized with the cycle on a basis of a clock signal.

6. The electronic circuit according to claim 4, wherein the second period is set according to an activation characteristic of the pre-stage circuit.

7. The electronic circuit according to claim 6, wherein the second period is set according to time to reach an operating point in a case where the first current is always supplied to the pre-stage circuit.

8. The electronic circuit according to claim 4, wherein the pre-stage circuit includes at least an amplifier that supplies an analog signal to the analog-to-digital converter.

9. The electronic circuit according to claim 8, wherein
the amplifier is configured by a plurality of amplifiers connected in parallel, and
the control circuit blocks a supply current to at least one amplifier among the plurality of amplifiers in the second period.

10. The electronic circuit according to claim 9, further comprising
a current source configured to supply the supply current to the pre-stage circuit, wherein
the control circuit controls a current output from the current source.

11. The electronic circuit according to claim 10, wherein
the pre-stage circuit includes:
a low noise amplifier that amplifies a signal in a high frequency region received by a reception antenna; and
a frequency mixer that converts a carrier frequency of an output signal of the low noise amplifier into a lower intermediate frequency by mixing an oscillation frequency of a voltage controlled oscillator, and
the amplifier amplifies a signal converted into an intermediate frequency by the frequency mixer.

12. The electronic circuit according to claim 10, wherein
the pre-stage circuit includes:
a low noise transconductance amplifier that operates on a capacitive load and amplifies a signal in a high frequency region received by a reception antenna;
a frequency mixer that converts a carrier frequency of an output signal of the low noise transconductance amplifier into a lower intermediate frequency by mixing an oscillation frequency of a voltage controlled oscillator; and
a transimpedance amplifier that amplifies a signal output from the frequency mixer as a voltage signal, and
the amplifier limits a band of a signal output from the transimpedance amplifier and amplifies a signal with reduced noise.

13. An AD conversion device comprising:
the electronic circuit according to claim 1; and
the analog-to-digital converter.

14. A communication device comprising:
a reception device including the electronic circuit according to claim 1; and
a transmission device.

15. A control method of a pre-stage circuit that supplies an analog signal to an analog-to-digital converter in which a first period and a second period are periodically and alternately repeated, the analog-to-digital converter performing different driving in the first period and the second period, the control method comprising:
inputting a clock signal; and
reducing a supply current to the pre-stage circuit according to the first period on a basis of a clock signal.
